(19) United States
(12) Patent Application Publication
(10) Pub. No.: US 2026/0094659 A1
(43) Pub. Date: Apr. 2, 2026

(54) SEMICONDUCTOR DEVICE

(71) Applicant: SK hynix Inc., Gyeonggi-do (KR)

(72) Inventors: Jeong Jun LEE, Gyeonggi-do (KR); Jun Ho CHEON, Gyeonggi-do (KR); Ho Seok EM, Gyeonggi-do (KR)

(21) Appl. No.: 19/014,224

(22) Filed: Jan. 9, 2025

(30) Foreign Application Priority Data
Sep. 27, 2024 (KR) 10-2024-0131449

(51) Int. Cl. G11C 29/42; G11C 29/14; G11C 29/44

(52) U.S. Cl. CPC G11C 29/42; G11C 29/14; G11C 29/44

(57) ABSTRACT

A semiconductor device may include a cell bank in which a plurality of normal data storage regions and a plurality of ECC data storage regions corresponding to different numbers of bit lines are disposed on layers that are stacked, in a three-dimensional matrix form and a peripheral layer electrically connected to the cell bank and disposed under the layers of the cell bank, wherein the peripheral layer includes internal circuits configured to control the cell bank, the internal circuits comprising a plurality of test circuits configured to identify whether all data output from the plurality of normal data storage regions and the plurality of ECC data storage regions are identical with each other.

### CROSS-REFERENCE TO RELATED APPLICATION

This patent application claims priority under 35 U.S.C. § 119(a) to Korean Patent Application No. 10-2024-0131449, filed on Sep. 27, 2024, the entire contents of which are incorporated herein by reference.

### BACKGROUND

### 1. Technical Field

Embodiments of the present disclosure relate to an integrated circuit technique and, more particularly, to a semiconductor device.

### 2. Related Art

Recently, as an electronic device is reduced in size, has lower power consumption and higher performance, and is diversified, a semiconductor device capable of storing information is required for various electronic devices, such as computers and portable communication devices. The semiconductor device may be basically divided into a volatile memory device and a nonvolatile memory device. The volatile memory device can retain data only in the state in which power is supplied to the volatile memory device. The nonvolatile memory device can retain data although power is not supplied to the nonvolatile memory device.

In order to reduce the size of a semiconductor device and increase the data storage capacity of the semiconductor device, the semiconductor device has been developed so that many memory cells can be integrated in the same area by reducing the width of a metal line in a two-dimensional (2-D) plane.

However, a technique for implementing a semiconductor device having a three-dimensional (3-D) structure is being developed because manufacturing equipment, investment costs, and a development period are increased exponentially as the width of the metal line in the 2-D plane is reduced.

### SUMMARY

In an embodiment of the present disclosure, a semiconductor device may include a cell bank in which a plurality of normal data storage regions and a plurality of ECC data storage regions corresponding to different numbers of bit lines are disposed on layers that are stacked, in a three-dimensional matrix form and a peripheral layer electrically connected to the cell bank and disposed under the layers of the cell bank, wherein the peripheral layer includes internal circuits configured to control the cell bank, the internal circuits comprising a plurality of test circuits configured to identify whether all data output from the plurality of normal data storage regions and the plurality of ECC data storage regions are identical with each other.

In an embodiment of the present disclosure, a semiconductor device may include a bank comprising at least one normal data storage region corresponding to a plurality of bit lines and at least one ECC data storage region corresponding to a smaller number of bit lines than each of the plurality of normal data storage regions and a test circuit configured to identify whether all data output from the plurality of normal data storage regions and data output from the ECC data storage region based on a column address that selects one bit line are identical with each other, wherein the test circuit identifies whether the data output from the normal data storage region and the data output from the ECC data storage region are identical with each other when a bit line included in the ECC data storage region is selected based on the column address, and identifies whether the data output from the normal data storage regions are identical with each other when a bit line included in the ECC data storage region is not selected based on the column address.

In an embodiment of the present disclosure, a semiconductor device may include a bank comprising first to sixteenth normal data storage regions and first to fourth ECC data storage regions, a first test circuit configured to identify, based on a most significant bit of a column address, whether data output from the first to eighth normal data storage regions are identical with each other or identify data output from the first to eighth normal data storage regions and data output from the first and second ECC data storage regions are identical with each other and a second test circuit configured to identify, based on the most significant bit of the column address, whether data output from the ninth to sixteenth normal data storage regions are identical with each other or identify whether data output from the ninth to sixteenth normal data storage regions and data output from the third and fourth ECC data storage regions are identical with each other.

### BRIEF DESCRIPTION OF THE DRAWINGS

FIG. 1 is a diagram for describing a bank having a 2-D structure included in a semiconductor device according to an embodiment of the present disclosure.

FIGS. 2 to 4 are diagrams for describing a 3-D structure of a bank according to embodiments of the present disclosure.

FIG. 5 is a diagram for describing a configuration of a semiconductor device according to an embodiment of the present disclosure.

FIG. 6 is a diagram for describing test circuits of a semiconductor device according to an embodiment of the present disclosure.

FIG. 7 is a diagram for describing a detailed configuration of test circuits included in a semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device capable of performing a normal operation even in a three-dimensional (3-D) structure.

It is possible to improve the reliability of a semiconductor device having a structure changed into a 3-D structure.

A semiconductor device may be configured to store data and output the stored data. In this case, the semiconductor device may include a memory cell in which data are stored. The memory cell may be coupled to a bit line and a word line. For example, the semiconductor device may include a plurality of memory cells coupled to a plurality of bit lines and a plurality of word lines, respectively. For example, the semiconductor device may be configured so that a memory cell that is connected between a selected bit line, among the plurality of bit lines, and a selected word line, among the plurality of word lines, is designated. In this case, the semiconductor device may be configured to store data in the designated memory cell and to output the stored data.

A semiconductor device may test whether memory cells store data normally. A repair operation may be performed on memory cells in which data are not stored normally.

For example, a semiconductor device may include a plurality of banks. Each of the plurality of banks may include a plurality of data storage regions. Each of the plurality of data storage regions may include a set number of memory cells.

The semiconductor device may determine a bank including memory cells in which data are not stored normally, among the plurality of banks, and may repair a bank including abnormal memory cells by using another bank. In this case, in order to determine the memory cells in which data are not stored normally, the semiconductor device may perform a test for storing the same data in all of the memory cells within the bank, outputting the data stored in all of the memory cells, and comparing the data. The semiconductor device may determine that the bank is normal when the data stored in all of the memory cells are identical with each other in the test, and may determine that the bank includes at least one abnormal memory cell when at least one datum stored in all of the memory cells is different in the test. A semiconductor device according to an embodiment of the present disclosure may be configured to determine a bank including memory cells in which data are not stored normally.

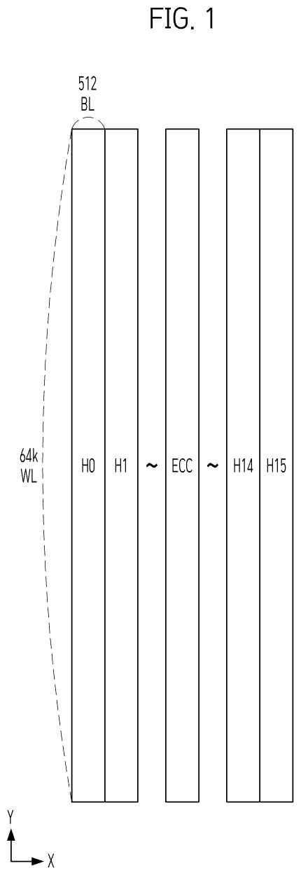

FIG. 1 is a diagram for describing a bank having a two-dimensional (2-D) structure included in a semiconductor device according to an embodiment of the present disclosure. In FIG. 1, one bank including seventeen data storage regions may be illustrated as an embodiment.

Referring to FIG. 1, the bank having the 2-D structure may include first to seventeenth data storage regions H0 to H15 and ECC. In this case, some (e.g., H0 to H15) of the first to seventeenth data storage regions H0 to H15 and ECC may be regions in which normal data are stored, and the remainder ECC may be a region in which ECC data necessary for the use of an error correction code (ECC) are stored.

In an embodiment, the first to seventeenth data storage regions H0 to H15 and ECC may be disposed in a first direction X. For example, the first to sixteenth data storage regions H0 to H15 in which the normal data are stored may be sequentially disposed in the first direction X. In this case, the seventeenth data storage region ECC in which the ECC data are stored may be disposed between the eighth data storage region H7 (not illustrated) and the ninth data storage region H8 (not illustrated).

Each of the first to seventeenth data storage regions H0 to H15 and ECC may include 64k word lines 64k WL and 512 bit lines 512 BL. In this case, k may refer to a decimal number 1024, and 64k may refers to 64*1024. Furthermore, one memory cell may be connected to a portion at which one word line and one bit line are intersected. Accordingly, the number of word lines and the number of bit lines may correspond to a data storage capacity.

Each of the 64k word lines 64k WL may be configured to be extended and formed in the first direction X.

Each of the 512 bit lines 512 BL may be configured to be extended and formed in a second direction Y. The first direction X and the second direction Y may be directions that intersect each other.

The bank having the 2-D structure constructed as described above may store the same data in the first to seventeenth data storage regions H0 to H15 and ECC, may output the data stored in the first to seventeenth data storage regions H0 to H15 and ECC from the data storage regions H0 to H15 and ECC, may compare the output data, and may determine that the bank includes at least one memory cell in which data are not stored normally when at least one datum is different.

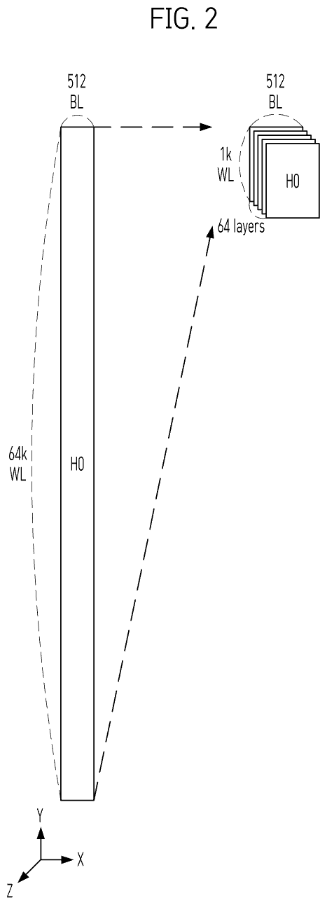

FIGS. 2 to 4 are diagrams for describing 3-D structures of banks according to embodiments of the present disclosure.

FIG. 2 is a diagram for comparing and describing data storage regions having a 2-D structure in which normal data are stored and normal data storage regions having a 3-D structure. In this case, FIG. 2 may illustrate the first data storage region H0 of FIG. 1 as an example.

Referring to FIG. 2, a data storage region H0 having a 2-D structure may have a plane structure that is defined in a first direction X and a second direction Y. A normal data storage region H0 having a 3-D structure may have a structure in which a plane structure that is defined in the first direction X and the second direction Y is stacked in a third direction Z. In this case, the third direction Z may be a direction that is orthogonal to a plane that is defined in the first direction X and the second direction Y.

For example, the data storage region H0 having the 2-D structure may include 64k word lines 64k WL and 512 bit lines 512 BL. The normal data storage region H0 having the 3-D structure may include 64k word lines 64k WL and 512 bit lines 512 BL. In this case, the normal data storage region H0 having the 3-D structure may be a structure in which 64 layers have been stacked. Each of the 64 layers may include 1k word lines 1k WL and 512 bit lines 512 BL.

Accordingly, the data storage region H0 having the 2-D structure and the normal data storage region H0 having the 3-D structure may have the same data storage capacity because the data storage region H0 having the 2-D structure and the normal data storage region H0 having the 3-D structure include the same number of word lines and the same number of bit lines.

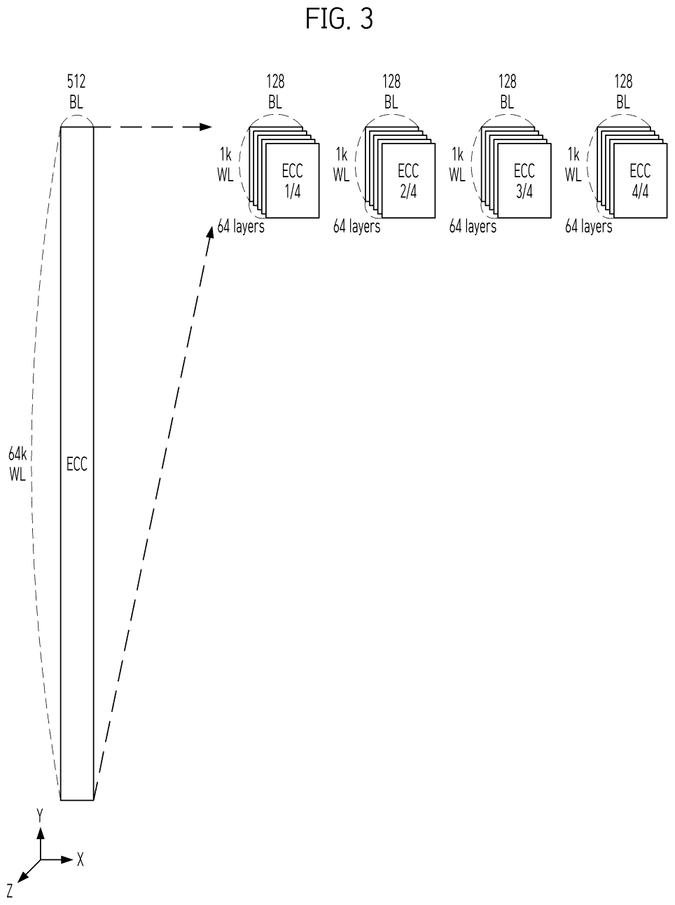

FIG. 3 is a diagram for comparing and describing a data storage region having a 2-D structure in which ECC data are stored and an ECC data storage region having a 3-D structure. In this case, FIG. 2 may illustrate the seventeenth data storage region ECC of FIG. 1 as an example. In this case, a data storage region ECC having a 2-D structure and ECC data storage regions ECC 1/4, ECC 2/4, ECC 3/4, and ECC 4/4 each having a 3-D structure may each be a region in which ECC data necessary for the use of an error correction code (ECC) are stored.

Referring to FIG. 3, the data storage region ECC having the 2-D structure may have a plane structure that is defined in a first direction X and a second direction Y. Each of the first to fourth ECC data storage regions ECC 1/4, ECC 2/4, ECC 3/4, and ECC 4/4 each having the 3-D structure may have a structure in which a plane structure that is defined in the first direction X and the second direction Y is stacked in a third direction Z. In this case, the third direction Z may be a direction that is orthogonal to a plane that is defined in the first direction X and the second direction Y. For example, the data storage region ECC having the 2-D structure may include 64k word lines 64k WL and 512 bit lines 512 BL. Each of the first to fourth ECC data storage regions ECC 1/4, ECC 2/4, ECC 3/4, and ECC 4/4 each having the 3-D structure may have a structure in which 64 layers have been stacked. Each of the 64 layers may include 1k word lines 1k WL and 128 bit lines 128 BL. Accordingly, a total number of word lines of the first to fourth ECC data storage regions ECC 1/4, ECC 2/4, ECC 3/4, and ECC 4/4 each having the 3-D structure may be 64k (i.e., 64k WL), and a total number of bit lines thereof may be 512 (i.e., 512 BL).

Therefore, the first to fourth ECC data storage regions ECC 1/4, ECC 2/4, ECC 3/4, and ECC 4/4 each having the 3-D structure may have the same data storage capacity because the total number of word lines and the total number of bit lines of the first to fourth ECC data storage regions ECC 1/4, ECC 2/4, ECC 3/4, and ECC 4/4 are the same as those of the data storage region ECC having the 2-D structure.

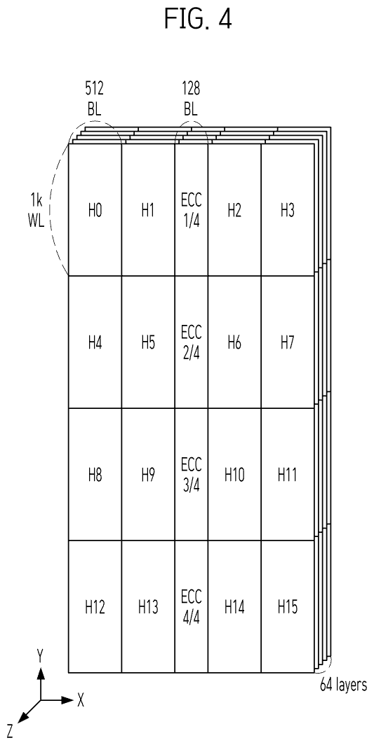

FIG. 4 is a diagram for describing a bank having a 3-D structure, which has the same data storage capacity as the bank having the 2-D structure, which is illustrated in FIG. 2. FIG. 4 is a diagram in which the bank having the 3-D structure has been constructed as an embodiment by using the normal data storage region H0 having the 3-D structure, which is illustrated in FIG. 2, and the first to fourth normal data storage regions ECC 1/4, ECC 2/4, ECC 3/4, and ECC 4/4 each having the 3-D structure, which are illustrated in FIG. 3. In this case, the bank having the 3-D structure may include a structure in which the data storage regions H0 to H15, ECC 1/4, ECC 2/4, ECC 3/4, and ECC 4/4 are disposed on a plane that is defined in a first direction X and a second direction Y in a matrix form and such a matrix form is stacked in a third direction Z. That is, the data storage regions H0 to H15, ECC 1/4, ECC 2/4, ECC 3/4, and ECC 4/4 are disposed on layers that are stacked, in a 3-D matrix form.

Referring to FIG. 4, one bank may include the first to sixteenth normal data storage regions H0 to H15 that store normal data and the first to fourth ECC data storage regions ECC 1/4, ECC 2/4, ECC 3/4, and ECC 4/4 that store ECC data.

The first to fourth normal data storage regions H0, H1, H2, and H3 may be disposed in the first direction X. In this case, the first ECC data storage region ECC 1/4 may be disposed between the second normal data storage region H1 and the third normal data storage region H2. That is, the first normal data storage region H0, the second normal data storage region H1, the first ECC data storage region ECC 1/4, the third normal data storage region H2, and the fourth normal data storage region H3 may be sequentially disposed in the first direction X.

The fifth to eighth normal data storage regions H4, H5, H6, and H7 may be disposed in the first direction X. In this case, the second ECC data storage region ECC 2/4 may be disposed between the sixth normal data storage region H5 and the seventh normal data storage region H6. That is, the fifth normal data storage region H4, the sixth normal data storage region H5, the second ECC data storage region ECC 2/4, the seventh normal data storage region H6, and the eighth normal data storage region H7 may be sequentially disposed in the first direction X. Furthermore, the fifth normal data storage region H4 may be disposed to neighbor the first normal data storage region H0 in the second direction Y. The sixth normal data storage region H5 may be disposed to neighbor the second normal data storage region H1 in the second direction Y. The second ECC data storage region ECC 2/4 may be disposed to neighbor the first ECC data storage region ECC 1/4 in the second direction Y. The seventh normal data storage region H6 may be disposed to neighbor the third normal data storage region H2 in the second direction Y. The eighth normal data storage region H7 may be disposed to neighbor the fourth normal data storage region H3 in the second direction Y.

The ninth to twelfth normal data storage regions H8, H9, H10, and H11 may be disposed in the first direction X. In this case, the third ECC data storage region ECC 3/4 may be disposed between the tenth normal data storage region H9 and the eleventh normal data storage region H10. That is, the ninth normal data storage region H10, the tenth normal data storage region H11, the third ECC data storage region ECC 3/4, the eleventh normal data storage region H10, and the twelfth normal data storage region H11 may be sequentially disposed in the first direction X. Furthermore, the ninth normal data storage region H8 may be disposed to neighbor the fifth normal data storage region H4 in the second direction Y. The tenth normal data storage region H9 may be disposed to neighbor the sixth normal data storage region H5 in the second direction Y. The third ECC data storage region ECC 3/4 may be disposed to neighbor the second ECC data storage region ECC 2/4 in the second direction Y. The eleventh normal data storage region H10 may be disposed to neighbor the seventh normal data storage region H6 in the second direction Y. The twelfth normal data storage region H11 may be disposed to neighbor the eighth normal data storage region H7 in the second direction Y.

The thirteenth to sixteenth normal data storage region H12, H13, H14, and H15 may be disposed in the first direction X. In this case, the fourth ECC data storage region ECC 4/4 may be disposed between the fourteenth normal data storage region H13 and the fifteenth normal data storage region H14. That is, the thirteenth normal data storage region H12, the fourteenth normal data storage region H13, the fourth ECC data storage region ECC 4/4, the fifteenth normal data storage region H14, and the sixteenth normal data storage region H15 may be sequentially disposed in the first direction X. Furthermore, the thirteenth normal data storage region H12 may be disposed to neighbor the ninth normal data storage region H8 in the second direction Y. The fourteenth normal data storage region H13 may be disposed to neighbor the tenth normal data storage region H9 in the second direction Y. The fourth ECC data storage region ECC 4/4 may be disposed to neighbor the third ECC data storage region ECC 3/4 in the second direction Y. The fifteenth normal data storage region H14 may be disposed to neighbor the eleventh normal data storage region H10 in the second direction Y. The sixteenth normal data storage region H15 may be disposed to neighbor the twelfth normal data storage region H1 in the second direction Y.

The bank having the 2-D structure illustrated in FIG. 1 may include the first to seventeenth data storage regions H0 to H15 and ECC each having 64k word lines 64k WL and 512 bit lines 512 BL. The bank having the 3-D structure illustrated in FIG. 4 may include the first to sixteenth normal data storage regions H0 to H15 each having 64k word lines and the 512 bit lines and the first to fourth ECC data storage regions ECC 1/4, ECC 2/4, ECC 3/4, and ECC 4/4 each having 64k word lines and 128 bit lines. A total number of word lines and a total number of bit lines of the first to fourth ECC data storage regions ECC 1/4, ECC 2/4, ECC 3/4, and ECC 4/4 may be the same as those of one data storage region (e.g., the first data storage region H0) having a 2-D structure.

As a result, the bank having the 2-D structure illustrated in FIG. 1 and the bank having the 3-D structure illustrated in FIG. 4 may have the same data storage capacity because the banks have the same number of word lines and the same number of bit lines.

The 512 bit lines 512 BL included in each of the first to sixteenth normal data storage regions H0 to H15 may be configured so that at least one of the 512 bit lines 512 BL is selected based on a column address (not illustrated).

Furthermore, the 512 bit lines (i.e., 128+128+128+128=512) included in the first to fourth ECC data storage regions ECC 1/4, ECC 2/4, ECC 3/4, and ECC 4/4 may be configured so that at least one of the 512 bit lines is selected based on a column address (not illustrated). Accordingly, at least one of the first to fourth ECC data storage regions ECC 1/4, ECC 2/4, ECC 3/4, and ECC 4/4 may include a bit line that is selected based on the column address. For example, the first ECC data storage region ECC 1/4, among the first to fourth ECC data storage regions ECC 1/4, ECC 2/4, ECC 3/4, and ECC 4/4, may include at least one bit line that is selected by the column address. The second ECC data storage region ECC 2/4, among the first to fourth ECC data storage regions ECC 1/4, ECC 2/4, ECC 3/4, and ECC 4/4, may include at least one bit line that is selected by the column address. The third ECC data storage region ECC 3/4, among the first to fourth ECC data storage regions ECC 1/4, ECC 2/4, ECC 3/4, and ECC 4/4, may include at least one bit line that is selected by the column address. The fourth ECC data storage region ECC 4/4, among the first to fourth ECC data storage regions ECC 1/4, ECC 2/4, ECC 3/4, and ECC 4/4, may include at least one bit line that is selected by the column address.

Accordingly, each of the first to sixteenth normal data storage regions H0 to H15 and the first to fourth ECC data storage regions ECC 1/4, ECC 2/4, ECC 3/4, and ECC 4/4 may include at least one bit line that is selected based on the same column address, among the 512 bit lines 512 BL. Therefore, each of the first to sixteenth normal data storage regions H0 to H15 may include a bit line that is selected based on the same column address. Only one of the first to fourth ECC data storage regions ECC 1/4, ECC 2/4, ECC 3/4, and ECC 4/4 may include a selected bit line.

Each of the first to sixteenth normal data storage regions H0 to H15 may have a greater data storage capacity than each of the first to fourth ECC data storage regions ECC 1/4, ECC 2/4, ECC 3/4, and ECC 4/4 because each of the first to sixteenth normal data storage regions H0 to H15 has a larger number of bit lines than each of the first to fourth ECC data storage regions ECC 1/4, ECC 2/4, ECC 3/4, and ECC 4/4. Therefore, the first to sixteenth normal data storage regions H0 to H15 may each be named a big unit region, and the first to fourth ECC data storage regions may each be named a small unit region.

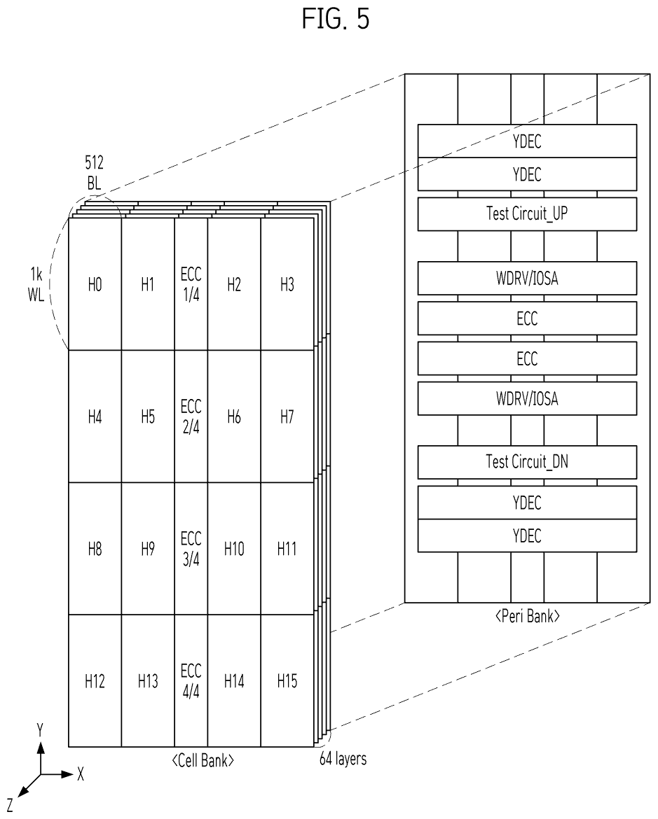

FIG. 5 is a diagram for describing a configuration of a semiconductor device according to an embodiment of the present disclosure. FIG. 5 is a diagram illustrating that the bank including memory cells illustrated in FIG. 4 is referred to as a cell bank and a region including internal circuits that control the cell bank is referred to as a peri-bank (i.e., peripheral layer). The cell bank and the peri-bank may be electrically connected through hybrid bonding.

Referring to FIG. 5, the semiconductor device according to an embodiment of the present disclosure may include the cell bank and the peri-bank.

A description of the cell bank is replaced with the description given with reference to FIG. 4.

The peri-bank may be electrically connected to the cell bank. The peri-bank may be disposed to neighbor the cell bank in a third direction Z. For example, the peri-bank may be disposed under the cell bank and electrically connected to the cell bank.

The peri-bank may include the internal circuits that control the cell bank. For example, the peri-bank may include a column decoder YDEC, a word line driver WDRV, a sense amplifier IOSA, an ECC circuit ECC, and test circuits Test Circuit_UP and Test Circuit_DN. The column decoder YDEC may selectively drive the bit lines of the cell bank based on a column address (not illustrated). The word line driver WDRV may selectively drive the word lines of the cell bank based on a row address (not illustrated). The sense amplifier IOSA may sense data that are stored in the memory cells of the cell bank. The ECC circuit ECC may correct an error of data that are sensed from the memory cells of the cell bank, that is, an error of data that are output after the start of a read operation. The test circuits Test Circuit_UP and Test Circuit_DN may be used when the semiconductor device is tested. For example, the test circuits Test Circuit_UP and Test Circuit_DN may test whether the memory cells of the cell bank store data normally.

In general, a semiconductor device including memory cells performs a redundancy operation of testing whether the memory cells store data normally and substituting memory cells having a defect based on the results of the test with normal memory cells.

The semiconductor device including the cell bank having the 3-D structure according to an embodiment of the present disclosure may also perform a redundancy operation of testing whether the memory cells of the cell bank store data normally and substituting memory cells having a defect based on the results of the test with normal memory cells. In this case, the test circuits Test Circuit_UP and Test Circuit_DN may be used.

For example, a test for identifying whether memory cells store data normally may include an operation of identifying whether all data stored in the memory cells are the same after a write operation of storing data having the same level in all of the memory cells included in the cell bank is performed.

The test circuits Test Circuit_UP and Test Circuit_DN may be circuits for identifying whether all data sensed from memory cells are the same.

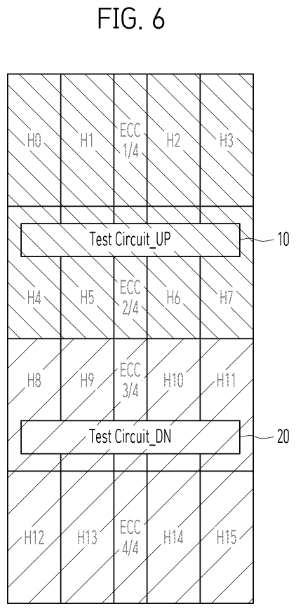

FIG. 6 is a diagram for describing test circuits of a semiconductor device according to an embodiment of the present disclosure.

Referring to FIG. 6, the test circuits Test Circuit_UP and Test Circuit_DN of the semiconductor device according to an embodiment of the present disclosure may include a first test circuit Test Circuit_UP 10 and a second test circuit Test Circuit_DN 20.

The first test circuit 10 may identify whether all data output from some memory cells of the cell bank are the same.

The second test circuit 20 may identify whether all data output from the remaining memory cells of the cell bank are the same.

The first test circuit 10 may be disposed under a region in which the fifth to eighth normal data storage regions H4 to H7 and the second ECC data storage region ECC 2/4 are disposed. The second test circuit 20 may be disposed under a region in which the ninth to twelfth normal data storage regions H8 to H11 and the third ECC data storage region ECC 3/4 are disposed.

The first test circuit 10 may be configured to identify whether all data output from the first to eighth normal data storage regions H0 to H7 and the first and second ECC data storage regions ECC 1/4 and ECC 2/4 included in the cell bank are the same. Furthermore, the second test circuit 20 may be configured to identify whether all data output from the ninth to sixteenth normal data storage regions H9 to H15 and the third and fourth ECC data storage regions ECC 3/4 and ECC 4/4 included in the cell bank are the same. The reason why each of the first and second test circuits 10 and 20 is disposed under a data storage region to be tested is to minimize the length of a wire.

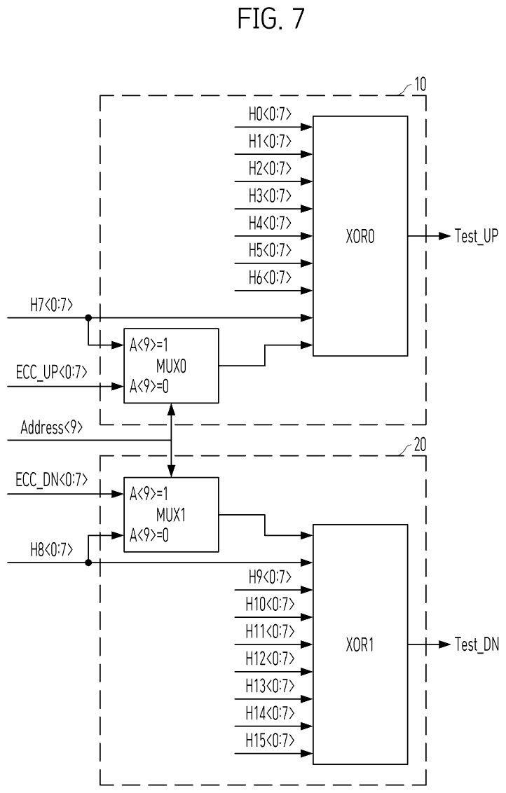

FIG. 7 is a diagram for describing a detailed configuration of the test circuit included in the semiconductor device according to an embodiment of the present disclosure. FIG. 7 may be a figure illustrating the first test circuit 10 and the second test circuit 20 illustrated in FIG. 6.

Referring to FIG. 7, the first and second test circuits 10 and 20 may include selection circuits MUX0 and MUX1 and data comparison circuits XOR0 and XOR1, respectively.

The first test circuit 10 may be configured to identify whether all data that are output from the first to eighth normal data storage regions H0 to H7 and the first and second ECC data storage regions ECC 1/4 and ECC 2/4 included in the cell bank are the same.

The first test circuit 10 may include a multiplexer (i.e., a selection circuit) MUX0 as the selection circuit MUX0 and an exclusive OR gate (i.e., a data comparison circuit) XOR0 as the data comparison circuit XOR0.

The multiplexer MUX0 may provide the exclusive OR gate XOR0 with one of data H7<0:7> that are output from the eighth normal data storage region H7 and data ECC_UP<0:7>that are output from the first and second normal data storage regions ECC 1/4 and ECC 2/4, based on the highest column address (i.e., the highest bit of column address) Address<9>. For example, when the highest column address address<9> is at a high level 1, the multiplexer MUX0 may provide the exclusive OR gate XOR0 with the data H7<0:7> that are output from the eighth normal data storage region H7. When the highest column address address<9> is at a low level 0, the multiplexer MUX0 may provide the exclusive OR gate XOR0 with the data ECC_UP<0:7> that are output from the first and second normal data storage regions ECC 1/4 and ECC 2/4.

The exclusive OR gate XOR0 may identify whether all data H0<0:7>, H1<0:7>, H2<0:7>, H3<0:7>, H4<0:7>, H5<0:7>, H6<0:7>, and H7<0:7> that are output from the first to eighth normal data storage regions H0 to H7 and data that are output from the multiplexer MUX0 have the same data value. For example, when all input data have the same value, the exclusive OR gate XOR0 may output a test result signal Test_UP being at a low level 0. When any one of the input data has a different data value, the exclusive OR gate XOR0 may output the test result signal Test_UP being at a high level 1. In this case, the data that are output from the first normal data storage region H0 may be H0<0:7>. The data that are output from the second normal data storage region H1 may be H1<0:7>. The data that are output from the third normal data storage region H2 may be H2<0:7>. The data that are output from the fourth normal data storage region H3 may be H3<0:7>. The data that are output from the fifth normal data storage region H4 may be H4<0:7>. The data that are output from the sixth normal data storage region H5 may be H5<0:7>. The data that are output from the seventh normal data storage region H6 may be H6<0:7>. The data that are output from the eighth normal data storage region H8 may be H7<0:7>. Furthermore, the data that are output from one of the first and second ECC data storage regions ECC 1/4 and ECC 2/4 may be ECC_UP<0:7>.

The second test circuit 10 may include a multiplexer (i.e., a selection circuit) MUX1 as the selection circuit MUX1 and an exclusive OR gate (i.e., a data comparison circuit) XOR1 as the data comparison circuit XOR1.

The multiplexer MUX1 may provide the exclusive OR gate XOR1 with one of data H8<0:7> that are output from the ninth normal data storage region H8 and data ECC_DN<0:7> that are output from the third and fourth normal data storage regions ECC 3/4 and ECC 4/4, based on the highest column address Address<9>. For example, when the highest column address address<9> is at a high level 1, the multiplexer MUX0 may provide the exclusive OR gate XOR1 with the data ECC_DN<0:7> that are output from the third and fourth normal data storage regions ECC 3/4 and ECC 4/4. When the highest column address address<9> is at a low level 0, the multiplexer MUX0 may provide the exclusive OR gate XOR1 with the data H8<0:7> that are output from the ninth normal data storage region H8.

The exclusive OR gate XOR1 may identify whether all data H8<0:7>, H9<0:7>, H10<0:7>, H11<0:7>, H12<0:7>, H13<0:7>, H14<0:7>, and H15<0:7> that are output from the ninth to sixteenth normal data storage regions H9 to H16 and data that are output from the multiplexer MUX1 have the same data value. For example, when all input data have the same value, the exclusive OR gate XOR1 may output a test result signal Test_UP being at a low level 0. When any one of the input data has a different data value, the exclusive OR gate XOR0 may output the test result signal Test_UP being at a high level 1. In this case, the data that are output from the ninth normal data storage region H8 may be H8<0:7>. The data that are output from the tenth normal data storage region H9 may be H9<0:7>. The data that are output from the eleventh normal data storage region H10 may be H10<0:7>. The data that are output from the twelfth normal data storage region H11 may be H11<0:7>. The data that are output from the thirteenth normal data storage region H12 may be H12<0:7>. The data that are output from the fourteenth normal data storage region H13 may be H13<0:7>. The data that are output from the fifteenth normal data storage region H14 may be H14<0:7>. The data that are output from the sixteenth normal data storage region H15 may be H15<0:7>. Furthermore, the data that are output from one of the third and fourth ECC data storage regions ECC 3/4 and ECC 4/4 may be ECC_DN<0:7>.

In this case, the data H0<0:7> to H15<0:7> that are output from the first to sixteenth normal data storage regions H0 to H15, respectively, may be data that are output from memory cells that are connected to a bit line that is selected by the same column address. One of the data ECC_UP<0:7> and ECC_DN<0:7> may be output from the first to fourth ECC data storage regions ECC 1/4, ECC 2/4, ECC 3/4, and ECC 4/4 with respect to the same column address.

More specifically, each of the first to sixteenth normal data storage regions H0 to H15 may include one selected bit line, among the 512 bit lines, by a column address capable of selecting one of the 512 bit lines. Accordingly, each of the first to sixteenth normal data storage regions H0 to H15 may output data from memory cells that are connected to the selected bit line. However, the first to fourth ECC data storage regions ECC 1/4, ECC 2/4, ECC 3/4, and ECC 4/4 may select one of the total of 512 bit lines by the column address capable of selecting one of the 512 bit lines. Accordingly, only one of the first to fourth ECC data storage regions ECC 1/4, ECC 2/4, ECC 3/4, and ECC 4/4 may include the selected bit line. Therefore, the data that are output from the first to fourth ECC data storage regions ECC 1/4, ECC 2/4, ECC 3/4, and ECC 4/4 by the column address may be the data ECC_UP<0:7> that are output from the first and second ECC data storage regions ECC 1/4 and ECC 2/4 or the data ECC_DN<0:7> that are output from the third and fourth ECC data storage regions ECC 3/4 and ECC 4/4.

As a result, the data that are output from the first to fourth ECC data storage regions ECC 1/4, ECC 2/4, ECC 3/4, and ECC 4/4 by the column address that selects one of the 512 bit lines may be one of the data ECC_UP<0:7> and ECC_DN<0:7>. The other of the data ECC_UP<0:7> and ECC_DN<0:7> might not be data that are output from the memory cells.

The first and second ECC data storage regions ECC 1/4 and ECC 2/4 may include upper 256 bit lines, among the 512 bit lines included in the first to fourth ECC data storage regions ECC 1/4, ECC 2/4, ECC 3/4, and ECC 4/4. The third and fourth ECC data storage regions ECC 3/4, and ECC 4/4 may include lower 256 bit lines, among the 512 bit lines included in the first to fourth ECC data storage regions ECC 1/4, ECC 2/4, ECC 3/4, and ECC 4/4. In this case, whether a selected bit line is one of the upper 256 bit lines or one of the lower 256 bit lines may be determined by the most significant bit of a column address.

Accordingly, which one of the data ECC_UP<0:7> and ECC_DN<0:7> that are output from the first to fourth ECC data storage regions ECC 1/4, ECC 2/4, ECC 3/4, and ECC 4/4 corresponds to data that are output from a memory cell may be identified based on the most significant bit of the column address by identifying whether the selected bit line is included in the first and second ECC data storage regions ECC 1/4 and ECC 2/4 or the third and fourth ECC data storage regions ECC 3/4 and ECC 4/4.

As illustrated in FIG. 7, the first test circuit 10 is configured to identify whether data that are output from the first to seventeenth normal data storage regions H0 to H6 and data that are output from the first and second ECC data storage regions ECC 1/4 and ECC 2/4 are identical with each other. The second test circuit 20 is configured to identify whether data that are output from the eighth to sixteenth normal data storage regions H7 to H15 and data that are output from the third and fourth ECC data storage regions ECC 3/4 and ECC 4/4 are identical with each other.

Each of the first to sixteenth normal data storage regions H0 to H15 may output the data H0<0:7> to H15<0:7> from memory cells that are connected to a selected bit line based on a column address capable of selecting one of the 512 bit lines. However, only one of the data ECC_UP<0:7> and ECC_DN<0:7> may be data that are output from a memory cell because only one of the first to fourth ECC data storage regions ECC 1/4, ECC 2/4, ECC 3/4, and ECC 4/4 can include the selected bit line based on the column address capable of selecting one of the 512 bit lines. Accordingly, each of the first and second test circuits 10 and 20 includes the multiplexers MUX0 and MUX1 and the exclusive OR gates XOR0 and XOR1, respectively. Based on the most significant bit (e.g., the highest bit of column address Address<9>) of a column address, one of the first and second test circuits 10 and 20 may be configured to identify whether data that are output from the normal data storage regions and data that are output from the ECC data storage regions are identical with each other, and the other of the first and second test circuits 10 and 20 may be configured to identify whether data that are output from the normal data storage regions are identical with each other.

More specifically, for example, the first and second test circuits 10 and 20 may operate as follows.

When the highest column address Address<9> is at a low level, the multiplexer MUX0 may select and output the data ECC_UP<0:7> of the first and second ECC data storage regions ECC 1/4 and ECC 2/4, and the multiplexer MUX1 may select and output the data H8<0:7> of the ninth normal data storage region H8.

Accordingly, the first test circuit 10 may output the test result signal Test_UP by identifying whether all of the data H0<0:7>, H1<0:7>, H2<0:7>, H3<0:7>, H4<0:7>, H5<0:7>, H6<0:7>, and H7<0:7> that are output from the first to eighth normal data storage regions H0 to H7 and the data ECC_UP<0:7> that are output from the first and second ECC data storage regions ECC 1/4 and ECC 2/4 are identical with each other. Furthermore, the second test circuit 20 may output the test result signal Test_DN by identifying whether all of the data H8<0:7>, H9<0:7>, H10<0:7>, H11<0:7>, H12<0:7>, H13<0:7>, H14<0:7>, and H15<0:7>that are output from the ninth to sixteenth normal data storage regions H8 to H15 are identical with each other. In this case, the exclusive OR gate XOR1 of the second test circuit 20 may receive the data H8<0:7>, H9<0:7>, H10<0:7>, H11<0:7>, H12<0:7>, H13<0:7>, H14<0:7>, and H15<0:7> that are output from the ninth to sixteenth normal data storage regions H8 to H15 and the data H8<0:7> that are output from the multiplexer MUX1.

When the highest column address Address<9> is at a high level, the multiplexer MUX0 may output the data H7<0:7> that are output from the eighth normal data storage region H7, and the multiplexer MUX1 may output the data ECC_DN<0:7> that are output from the third and fourth ECC data storage regions ECC 3/4 and ECC 4/4.

Accordingly, the first test circuit 10 may output the test result signal Test_UP by identifying whether all of the data H0<0:7>, H1<0:7>, H2<0:7>, H3<0:7>, H4<0:7>, H5<0:7>, H6<0:7>, and H7<0:7> that are output from the first to eighth normal data storage regions H0 to H7 are identical with each other. In this case, the exclusive OR gate XOR0 of the first test circuit 10 may receive the data H8<0:7>, H9<0:7>, H10<0:7>, H11<0:7>, H12<0:7>, H13<0:7>, H14<0:7>, and H15<0:7> that are output from the first to eighth normal data storage regions H8 to H15 and the data H7<0:7> that are output from the multiplexer MUX0.

Furthermore, the second test circuit 20 may output the test result signal Test_DN by identifying whether all of the data H8<0:7>, H9<0:7>, H10<0:7>, H11<0:7>, H12<0:7>, H13<0:7>, H14<0:7>, and H15<0:7> that are output from the ninth to sixteenth normal data storage regions H8 to H15 and the data ECC_DN<0:7> that are output from the third and fourth ECC data storage regions ECC 3/4 and ECC 4/4 are identical with each other.

The bank of the semiconductor device according to an embodiment of the present disclosure is configured to include the first to fourth ECC data storage regions ECC 1/4, ECC 2/4, ECC 3/4, and ECC 4/4 including the 512 bit lines that are divided into four groups each including 128 bit lines. Furthermore, the most significant bit (e.g., the highest bit of column address) of a column address that selects the 512 bit lines may be a column address that distinguishes between the upper 256 bit lines and the lower 256 bit lines. Accordingly, in the embodiments of the present disclosure, an example in which the highest column address is used as a selection control signal for the multiplexers MUX0 and MUX1 in order to distinguish between a case in which a bit line included in the first and second ECC data storage regions ECC 1/4 and ECC 2/4 including the upper 256 bit lines is selected and a case in which a bit line included in the third and fourth ECC data storage regions ECC 3/4 and ECC 4/4 including the lower 256 bit lines is selected may have been described.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure. Furthermore, the embodiments may be combined to form additional embodiments.

What is claimed is:

1. A semiconductor device comprising:
a cell bank in which a plurality of normal data storage regions and a plurality of ECC data storage regions corresponding to different numbers of bit lines are disposed on layers that are stacked, in a three-dimensional matrix form; and
a peripheral layer electrically connected to the cell bank and disposed under the layers of the cell bank,
wherein the peripheral layer includes internal circuits configured to control the cell bank, the internal circuits comprising a plurality of test circuits configured to identify whether all data output from the plurality of normal data storage regions and the plurality of ECC data storage regions are identical with each other.

2. The semiconductor device of claim 1, wherein a number of bit lines corresponding to each of the plurality of normal data storage regions is identical with a total number of bit lines corresponding to the plurality of ECC data storage regions.

3. The semiconductor device of claim 2, wherein the plurality of test circuits comprises:
a first test circuit configured to receive data from some of the plurality of normal data storage regions and some of the plurality of ECC data storage regions; and
a second test circuit configured to receive data from a remainder of the plurality of normal data storage regions and a remainder of the plurality of ECC data storage regions.

4. The semiconductor device of claim 3, wherein the peripheral layer is configured so that the first test circuit is disposed under the some of the plurality of normal data storage regions and the some of the plurality of ECC data storage regions, and the second test circuit is disposed under the remainder of the plurality of normal data storage regions and the remainder of the plurality of ECC data storage regions.

5. The semiconductor device of claim 3, wherein:
the first test circuit is configured to identify whether data output from the normal data storage region and the ECC data storage region based on a column address are identical with each other; and
the second test circuit is configured to identify whether data output from the normal data storage regions based on the column address are identical with each other.

6. The semiconductor device of claim 5, wherein the first and second test circuits are configured to perform identification based on a most significant bit of the column address.

7. The semiconductor device of claim 6, wherein each of the first and second test circuits comprises:
a multiplexer configured to select one of the data output from the normal data storage region and the data output from the ECC data storage region based on the most significant bit of the column address; and
an exclusive OR gate configured to identify whether all data output from the multiplexer and the data output from the normal data storage regions are identical with each other.

8. A semiconductor device comprising:
a bank comprising at least one normal data storage region corresponding to a plurality of bit lines and at least one ECC data storage region corresponding to a smaller number of bit lines than each of the plurality of normal data storage regions; and
a test circuit configured to identify whether all data output from the plurality of normal data storage regions and data output from the ECC data storage region based on a column address that selects one bit line are identical with each other,
wherein the test circuit identifies whether the data output from the normal data storage region and the data output from the ECC data storage region are identical with each other when a bit line included in the ECC data storage region is selected based on the column address, and identifies whether the data output from the normal data storage regions are identical with each other when a bit line included in the ECC data storage region is not selected based on the column address.

9. The semiconductor device of claim 8, wherein the test circuit comprises:
a multiplexer configured to output one of the data output from the normal data storage region and the data output from the ECC data storage region based on a most significant bit of the column address, and
an exclusive OR gate configured to identify whether all data that are output from the normal data storage region and the output of the multiplexer are identical with each other.

10. A semiconductor device comprising:
a bank comprising first to sixteenth normal data storage regions and first to fourth ECC data storage regions;
a first test circuit configured to identify, based on a most significant bit of a column address, whether data output from the first to eighth normal data storage regions are identical with each other or identify data output from the first to eighth normal data storage regions and data output from the first and second ECC data storage regions are identical with each other; and
a second test circuit configured to identify, based on the most significant bit of the column address, whether data output from the ninth to sixteenth normal data storage regions are identical with each other or identify whether data output from the ninth to sixteenth normal data storage regions and data output from the third and fourth ECC data storage regions are identical with each other.

11. The semiconductor device of claim 10, wherein the first test circuit is configured to:
identify whether the data output from the first to eighth normal data storage regions are identical with each other when the most significant bit of the column address is at a first level; and
identify whether the data output from the first to eighth normal data storage regions and the data output from the first and second ECC data storage regions are identical with each other when the most significant bit of the column address is at a second level.

12. The semiconductor device of claim 11, wherein the second test circuit is configured to:
identify whether the data output from the ninth to sixteenth normal data storage regions and the data output from the third and fourth ECC data storage regions are identical with each other when the most significant bit of the column address is at the first level; and
identify whether the data output from the ninth to sixteenth normal data storage regions are identical with each other when the most significant bit of the column address is at the second level.

13. The semiconductor device of claim 11, wherein the first test circuit comprises:
a selection circuit configured to output the data output from the eighth normal data storage region or the data output from the first and second ECC data storage regions based on the most significant bit of the column address; and
a data comparison circuit configured to identify whether the data output from the first to eighth normal data storage regions and the data output from the selection circuit are identical with each other.

14. The semiconductor device of claim 13, wherein:
the selection circuit comprises a multiplexer that uses the most significant bit of the column address as a selection control signal, and
the data comparison circuit comprises an exclusive OR gate.

15. The semiconductor device of claim 12, wherein the second test circuit comprises:
a selection circuit configured to output the data output from the ninth normal data storage region or output the data output from the third and fourth ECC data storage regions based on the most significant bit of the column address; and
a data comparison circuit configured to identify whether the data output from the ninth to sixteenth normal data storage regions and the data output from the selection circuit are identical with each other.

16. The semiconductor device of claim 15, wherein:
the selection circuit comprises a multiplexer using the most significant bit of the column address as a selection control signal, and
the data comparison circuit comprises an exclusive OR gate.

17. The semiconductor device of claim 10, wherein:
each of the first to sixteenth normal data storage regions corresponds to 512 bit lines, and
each of the first to fourth ECC data storage regions corresponds to 128 bit lines.

18. The semiconductor device of claim 17, wherein the most significant bit of the column address distinguishes the first and second ECC data storage regions from the third and fourth ECC data storage regions.
